(19) United States
(12) Patent Application Publication
(10) Pub. No.: US 2014/0012525 A1
(43) Pub. Date: Jan. 9, 2014

(54) POWER MEASURING APPARATUS AND OPERATING METHOD THEREOF

(71) Applicants: KOREA ELECTRIC POWER CORPORATION, Seoul (KR); SAMSUNG ELECTRO-MECHANICS CO., LTD., Suwon (KR)

(72) Inventor: Min Gyu KIM, Gyunggi-do (KR)

(21) Appl. No.: 13/932,408

(22) Filed: Jul. 1, 2013

(30) Foreign Application Priority Data
Jul. 3, 2012 (KR) 10-2012-0072402

(51) Int. Cl. G01R 21/133

(52) U.S. Cl. CPC G01R 21/133
USPC 702/61

(57) ABSTRACT

There are provided a power measuring apparatus capable of accurately obtaining metering information and being manufactured at low cost by storing the metering information in an internal flash memory and an operating method thereof. The power measuring apparatus includes: a controlling unit controlling processing of consumed power metering information; a flash memory storing the metering information according to the controlling of the controlling unit and storing an operating program with respect to the processing of the metering information; and a random access memory providing a substitution program substituting the operating program while the metering information is stored in a specific address of the flash memory.

### CROSS-REFERENCE TO RELATED APPLICATIONS

This application claims the priority of Korean Patent Application No. 10-2012-0072402 filed on Jul. 3, 2012, in the Korean Intellectual Property Office, the disclosure of which is incorporated herein by reference.

### BACKGROUND OF THE INVENTION

1. Field of the Invention

The present invention relates to a power measuring apparatus capable of accurately obtaining metering information and an operating method thereof.

2. Description of the Related Art

Recently, electronic devices have increasingly been used in daily life due to increases in the diversity of functions thereof, greater utilization by users thereof, and the like.

An example of an electronic device may include a meter for metering power, gas, water, or the like supplied to a home, a building, or the like.

Such a meter has performed metering in a manner in which a physical amount of power, gas, water, or the like, is measured, after which a meter reader directly checks the meter with the naked eye to send the measurements to a central processing facility.

Meanwhile, in accordance with a development of communications technologies such as a remote area wireless communications, data communications, and the like, as in the invention described in the related art document, an electronic meter measuring a physical amount of supplied power, gas, water, and the like and sending the measured physical amount through wired and wireless communications means has been utilized.

Such an electronic meter has frequently stored metering information in an external Electrically Erasable Programmable Read-Only Memory (EEPROM) or a Ferroelectric Random Access Memory (FRAM) as a backup against blackouts or sudden malfunctions. In addition, the electronic power measuring apparatus generates an interrupt signal when updating software of a microprocessor through a wired or a wireless communications means or in the case that a meter case is opened in order to change a check date, a charging system, or the like, and even when such an external interrupt signal is generated, the metering information needs to be stored in a memory such as the external EEPROM or FRAM. However, the memory such as the EEPROM or FRAM may slowly read and write, such that the possibility of the occurrence of malfunctions may be increased, and the memory is used at the outside such that manufacturing costs may be increased.

[Related Art Document]

(Patent Document 1) Korean Patent Laid-Open Publication No. 10-2002-0023742

### SUMMARY OF THE INVENTION

An aspect of the present invention provides a power measuring apparatus capable of accurately obtaining metering information and able to be manufactured at low cost by storing the metering information in an internal flash memory and an operating method thereof.

According to an aspect of the present invention, there is provided a power measuring apparatus, including: a controlling unit controlling processing of consumed power metering information; a flash memory storing the metering information according to the controlling of the controlling unit and storing an operating program with respect to the processing of the metering information; and a random access memory providing a substitution program substituting the operating program while the metering information is stored in a specific address of the flash memory.

The flash memory may include: a metering calculation region in which measured metering information is calculated, an operating program region in which the operating program is stored, an interrupt service routine region providing a corresponding service routine when a preset internal interrupt is generated, and a data region providing a data storage address.

The random access memory may provide a corresponding service routine when a non-preset external interrupt is generated.

The power measuring apparatus may further include a measuring unit having a metering algorithm measuring the metering information.

According to an aspect of the present invention, there is provided a method of operating a power measuring apparatus, including: calculating measured metering information; providing a corresponding service routine stored in a flash memory when a preset internal interrupt is generated; and providing a corresponding service routine stored in a random access memory when a non-preset external interrupt is generated.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a power measuring apparatus according to an embodiment of the present invention;

FIG. 2 is an enlarged block diagram of certain blocks of the power measuring apparatus according to the embodiment of the present invention;

FIG. 3 is a flowchart showing an order of operations of the power measuring apparatus according to the embodiment of the present invention; and

FIGS. 4A through 4C are diagrams showing stable operations of the power measuring apparatus according to the embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

Throughout the drawings, the same or like reference numerals will be used to designate the same or like elements.

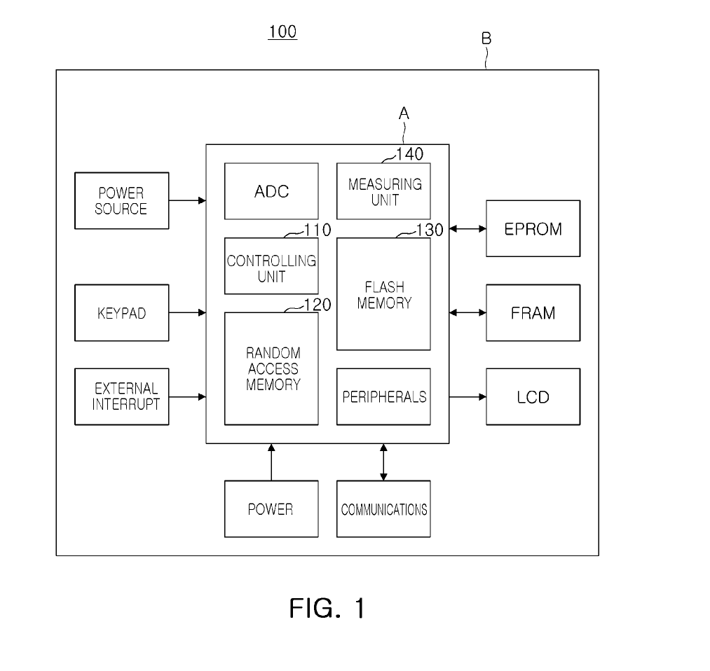

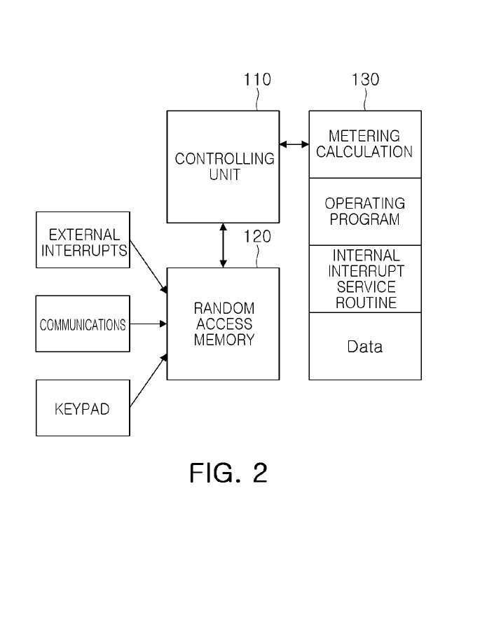

FIG. 1 is a schematic block diagram of a power measuring apparatus according to an embodiment of the present invention and FIG. 2 is an enlarged block diagram of certain blocks of the power measuring apparatus according to the embodiment of the present invention.

Referring to FIG. 1, a power measuring apparatus 100 according to the embodiment of the present invention may include a micro-controller A performing an operation of the power measuring apparatus, and the micro-controller A may have a keypad, an Electrically Erasable Programmable Read-Only Memory (EEPROM), a Ferroelectric Random Access Memory (FRAM), a liquid crystal display (LCD), or the like, connected to a periphery thereof. A power source, power, communications, and the like to be measured may be provided to the micro-controller A, and an external interrupt may also be delivered to the micro-controller A.

The micro-controller A may include an analog to digital converter (ADC) converting an analog signal from the power source to be measured into a digital signal, a controlling unit 110, a random access memory (RAM) 120, a flash memory 130, a measuring unit 140 having a metering algorithm containing metering information, peripherals for data communications and display, and the like.

Referring to FIGS. 1 and 2, the controlling unit 110 may perform a control with respect to a general metering operation of the power measuring apparatus and an operating program with respect to the control may be provided from the flash memory 130 or the random access memory 120.

The flash memory 130 may include a metering calculation region in which the measured metering information is calculated, an operating program region in which the operating program is stored, an interrupt service routine region providing a corresponding service routine when a preset internal interrupt is generated, and a data region providing a data storage address. Here, the preset internal interrupt may refer to an interrupt, the generation time of which may be predicted.

The random access memory 120 may store a substitution program substituting the operating program and may provide a corresponding service routine in the case in which the generated interrupt is a non-preset external interrupt. Here, the non-preset external interrupt may refer to an interrupt, the generation time of which may not be predicted.

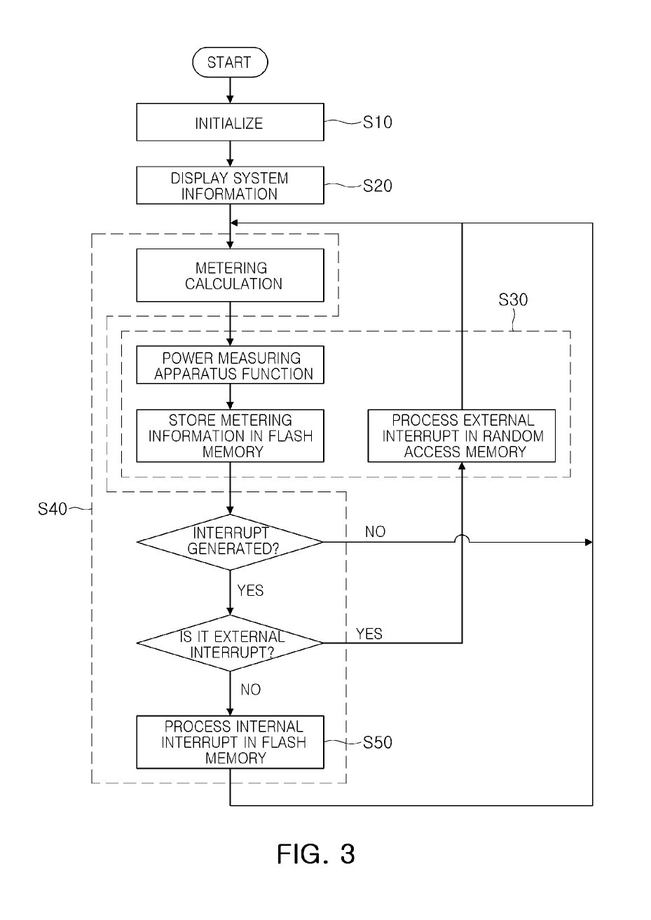

FIG. 3 is a flowchart showing an order of operations of the power measuring apparatus according to the embodiment of the present invention.

Referring to FIGS. 2 and 3, first, when the operation of the power measuring apparatus 100 starts, respective set values may be initialized (S10).

Thereafter, initialized system information may be displayed (S20), the power source to be measured input to the power measuring apparatus 100 may be converted into a digital signal through the ADC, and the measuring unit may measure an amount of consumed power based on the converted digital signal. In this case, the flash memory 130 may perform a metering calculation on the measured power amount (S30).

Finally, the metering information by the calculation may be stored in the flash memory 130 (S40).

Meanwhile, the interrupt may be generated while the metering information is stored in a specific address of the flash memory 130. In the case in which the generated interrupt is an internal interrupt, the generation time of which is predicted in advance, the flash memory 130 may store an interrupt service routine with respect to the preset internal interrupt so as not to be interrupted in storing the metering information in the specific address to thereby provide a corresponding interrupt service routine.

On the other hand, in the case in which the generated interrupt is an external interrupt, the generation time of which is not predicted, the random access memory 120 may provide a corresponding interrupt service routine among the stored interrupt service routines.

For example, a time necessary for storing the metering information in the specific address of the flash memory 130 is in a range from tens of milliseconds to hundreds of milliseconds. When a non-preset interrupt instructing a storage of 128 bytes of data is generated, a large amount of data may be lost and it is likely that an error will be generated. In this case, in the case in which the controlling unit 110 controls the random access memory 120 to indicate an interrupt service routine address with respect to the corresponding external interrupt, the non-preset interrupt instructing the storage of 128 bytes of data maybe implemented by storing the data without data loss.

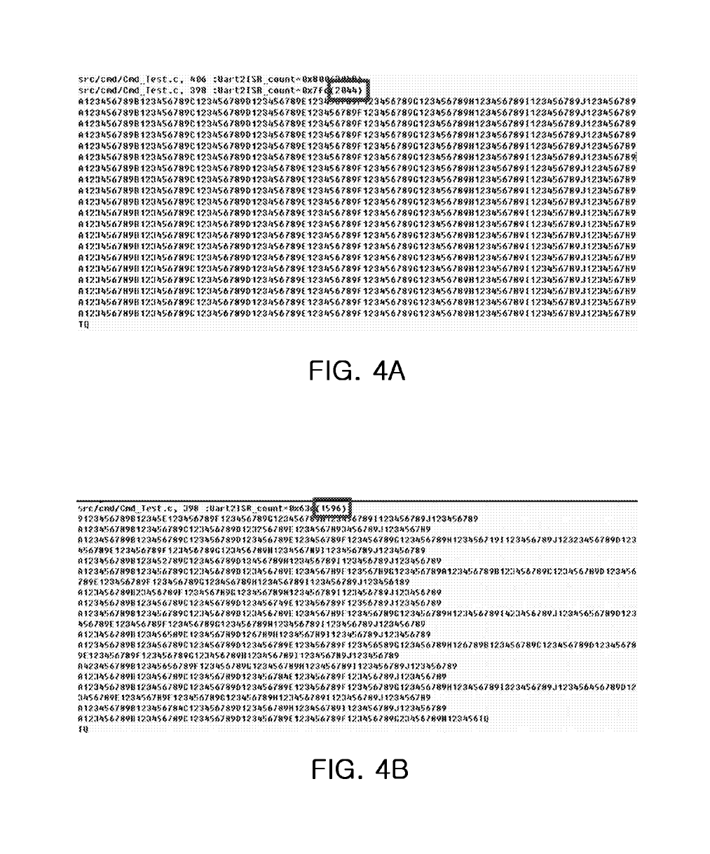

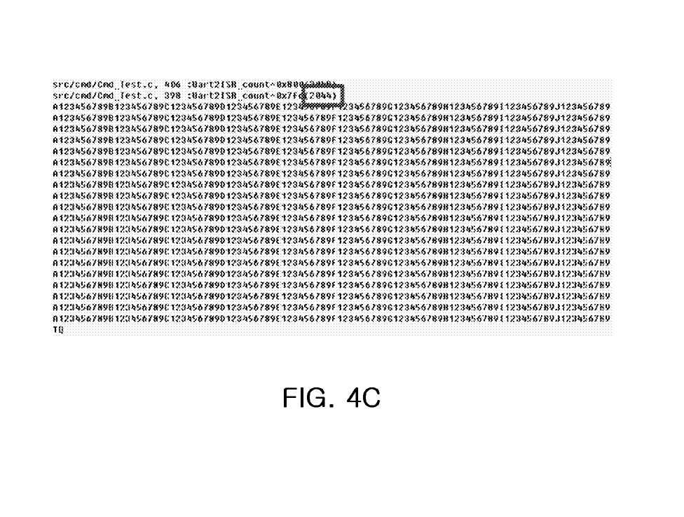

FIGS. 4A through 4C are diagrams showing stable operations of the power measuring apparatus according to the embodiment of the present invention.

FIG. 4A is an image received from the power measuring apparatus when 2044 bytes of data is interrupted in the case in which there is no operation of using a specific sector of the flash memory 130. In the case in which there is no operation of using a specific sector, it may be appreciated that no data loss is generated and the 2044 bytes of data is accurately received.

On the other hand, FIG. 4B is an image received from the power measuring apparatus when the 2044 bytes of data is interrupted during an operation of erasing a specific sector of the flash memory 130. In the case in which the interrupt is generated during the operation of using the specific sector, an amount of data received is 1596 bytes. Therefore, it may be appreciated that a large amount of data loss may be generated, as compared to 2044 bytes of raw data.

Finally, as shown in FIG. 4C, in the case in which the 2044 bytes of data is interrupted during the operation of erasing a specific sector of the flash memory 130, the controlling unit 110 controls the random access memory 120 to indicate the corresponding interrupt service routine address, and the 2044 bytes of data may be received by the power measuring apparatus without data loss due to the corresponding interrupt service routine.

As set forth above, a power measuring apparatus according to the embodiments of the invention may accurately obtain metering information and may be manufactured at low cost by storing the metering information in an internal flash memory to decrease the possibility of the occurrence of malfunctions.

While the present invention has been shown and described in connection with the embodiments, it will be apparent to those skilled in the art that modifications and variations can be made without departing from the spirit and scope of the invention as defined by the appended claims.

What is claimed is:

1. A power measuring apparatus, comprising:
a controlling unit controlling processing of consumed power metering information;
a flash memory storing the metering information according to the controlling of the controlling unit and storing an operating program with respect to the processing of the metering information; and
a random access memory providing a substitution program substituting the operating program while the metering information is stored in a specific address of the flash memory.

2. The power measuring apparatus of claim 1, wherein the flash memory includes:
a metering calculation region in which measured metering information is calculated;
an operating program region in which the operating program is stored;
an interrupt service routine region providing a corresponding service routine when a preset internal interrupt is generated; and
a data region providing a data storage address.

3. The power measuring apparatus of claim 2, wherein the random access memory provides a corresponding service routine when a non-preset external interrupt is generated.

4. The power measuring apparatus of claim 1, further comprising a measuring unit having a metering algorithm measuring the metering information.

5. A method of operating a power measuring apparatus, comprising:
calculating measured metering information;
providing a corresponding service routine stored in a flash memory when a preset internal interrupt is generated; and
providing a corresponding service routine stored in a random access memory when a non-preset external interrupt is generated.

6. The method of claim 5, wherein the flash memory includes:
a metering calculation region in which the measured metering information is calculated;
an operating program region in which an operating program is stored;
an interrupt service routine region providing a corresponding service routine when the preset internal interrupt is generated; and
a data region providing a data storage address.

7. The method of claim 6, wherein the random access memory provides a substitution program substituting the operating program while the metering information is stored in a specific address of the flash memory.
